(19) United States
(12) Patent Application Publication
(10) Pub. No.: US 2026/0239650 A1
(43) Pub. Date: Aug. 13, 2026

(54) ALUMINUM NITRIDE METAL-SEMICONDUCTOR FIELD-EFFECT TRANSISTORS ON SINGLE-CRYSTAL ALUMINUM NITRIDE SUBSTRATES

(71) Applicants: Houqiang Fu, Chandler, AZ (US); Bingcheng Da, Mesa, AZ (US); Dinusha Herath Mudiyanselage, Mesa, AZ (US)

(72) Inventors: Houqiang Fu, Chandler, AZ (US); Bingcheng Da, Mesa, AZ (US); Dinusha Herath Mudiyanselage, Mesa, AZ (US)

(21) Appl. No.: 19/468,911

(22) Filed: Feb. 3, 2026

Related U.S. Application Data
(60) Provisional application No. 63/756,933, filed on Feb. 11, 2025.

(51) Int. Cl. H10D 30/47; H10D 30/01; H10D 62/824; H10D 64/62

(52) U.S. Cl. CPC H10D 30/471; H10D 30/015; H10D 62/824; H10D 64/62

(57) ABSTRACT

A metal-semiconductor field effect transistor includes an AlN substrate, an AlN buffer layer on the AlN substrate, a Si-doped n-AlN layer on the AlN buffer layer, a GaN capping layer on the Si-doped n-AlN layer, a source contact on the GaN capping layer, a drain contact on the GaN capping layer, and a gate electrode on the GaN capping layer. Fabricating a metal-semiconductor field effect transistor includes depositing a first AlN layer on an AlN substrate via metal-organic chemical vapor deposition, depositing a second AlN layer on the first AlN layer, depositing a capping layer on the second AlN layer, forming a source contact and a drain contact on the capping layer via electron beam evaporation followed by rapid thermal annealing, and forming a gate electrode on the capping layer via electron beam evaporation. The second AlN layer includes silicon-doped AlN, and the capping layer includes unintentionally doped GaN.

### CROSS-REFERENCE TO RELATED APPLICATION

This application claims the benefit of U.S. Patent Application No. 63/756,933 filed on Feb. 11, 2025, which is incorporated by reference herein in its entirety.

### STATEMENT OF GOVERNMENT SUPPORT

This invention was made with government support under ECCS-2338604 awarded by the National Science Foundation. The government has certain rights in the invention.

### TECHNICAL FIELD

This invention relates to the field of ultra-wide bandgap semiconductors and high-power electronics.

### BACKGROUND

Aluminum nitride (AlN) is an ultra-wide bandgap material. It has a breakdown electric field of 12 MV/cm and a bandgap of 6.2 eV.

### SUMMARY

This disclosure describes the fabrication of aluminum nitride (AlN) metal-semiconductor field-effect transistors with homoepitaxially grown n-type AlN channel layers on single-crystal AlN substrates. Devices with a drain-to-gate length of 15μm demonstrate breakdown voltages that exceed 2 kV and exhibit drain saturation current and on/off ratio without regrown or graded contact layers. These results can provide references for developing high-performance AlN power devices for high-voltage high-power applications.

In a first general aspect, a metal-semiconductor field effect transistor includes an AlN substrate, an AlN buffer layer on the AlN substrate, a Si-doped n-AlN layer on the AlN buffer layer, a GaN capping layer on the Si-doped n-AlN layer, a source contact on the GaN capping layer, a drain contact on the GaN capping layer, and a gate electrode on the GaN capping layer.

Implementations of the first general aspect may include one or more of the following features.

In some cases, the AlN substrate includes a single-crystal AlN substrate. A dislocation density of the single-crystal AlN substrate can be about 10³ cm⁻². In some implementations, a thickness of the AlN buffer layer is about 1 μm. In certain cases, a thickness of the Si-doped n-AlN layer is about 200 nm. A thickness of the GaN capping layer can be about 2 nm. In some cases, the GaN capping layer is unintentionally doped. In certain cases, the source contact includes Ti/Al/Ni/Au. In some implementations, the drain contact includes Ti/Al/Ni/Au. The gate electrode can include Ni/Au. The AlN buffer layer is between the AlN substrate and the Si-doped n-AlN layer. In some cases, a breakdown voltage exceeds 2 kV for a drain-to-gate spacing of 15 μm. In certain implementations, a maximum drain current is about 56 μA/mm for a gate bias of +9 V. An ON/OFF ratio can be in a range of about 600 to about 800 for a drain-to-gate spacing of 8 μm. The metal-semiconductor field effect transistor can be thermally stable from 298 K to 423 K.

In a second general aspect, fabricating a metal-semiconductor field effect transistor includes depositing a first AlN layer on an AlN substrate via metal-organic chemical vapor deposition, depositing a second AlN layer on the first AlN layer, wherein the second AlN layer includes silicon-doped AlN, depositing a capping layer on the second AlN layer, wherein the capping layer includes unintentionally doped GaN, forming a source contact and a drain contact on the capping layer via electron beam evaporation followed by rapid thermal annealing, and forming a gate electrode on the capping layer via electron beam evaporation.

Implementations of the second general aspect may include one or more of the following features.

In some cases, the metal-organic chemical vapor deposition occurs at a temperature in a range of about 1100° C. to about 1300° C. In some implementations, the metal-organic chemical vapor deposition occurs at a pressure in a range of about 15 to about 25 Torr. The rapid thermal annealing can occur in a nitrogen atmosphere.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a schematic diagram of a fabricated aluminum nitride (AlN) metal-semiconductor field-effect transistor. FIG. 1B is a flowchart showing operations in an example process for fabricating a metal-semiconductor field effect transistor. FIG. 1C shows a top-view microscope image of a fabricated AlN metal-semiconductor field-effect transistor.

FIG. 2A shows I-V characteristics of n-AlN transmission line method structures at 298 K. The arrow indicates the direction of increasing gap between the transmission line method pads (d) from 5 μm to 25 μm. FIG. 2B shows I-V characteristics of n-AlN transmission line method structure with d=5 μm from 298 K to 423 K. The arrow indicates the direction of increasing temperature. FIG. 2C shows temperature-dependent sheet resistance (Rₛₕ) (represented by squares) and contact resistivity (ρ_{c}) (represented by circles) extracted from transmission line method measurements.

FIG. 3A shows drain current (I_{d})-drain bias (V_{ds}) characteristics of an AlN metal-semiconductor field-effect transistor with gate-to-drain length (L_{gd})=2 μm at room temperature. FIG. 3B shows transfer characteristics of AlN metal-semiconductor field-effect transistors with gate-to-drain lengths of 2 μm, 4 μm, and 8 μm and transconductance (dashed lines) of AlN metal-semiconductor field-effect transistors with gate-to-drain lengths of 2 μm, 4 μm, and 8 μm at room temperature. The arrow indicates the direction of increasing gate-to-drain lengths.

FIG. 4A shows reverse gate leakage current (I_{g})-gate voltage (V_{gd}) characteristics of AlN metal-semiconductor field-effect transistors at different temperatures, ranging from 298K to 423K. The arrow indicates the direction of increasing temperature. FIG. 4B shows transfer characteristics of AlN metal-semiconductor field-effect transistors at different temperatures, ranging from 298K to 423K. The arrow indicates the direction of increasing temperature. FIG. 4C shows temperature dependence of maximum drain current (I_{d,max}) (represented by filled circles) and maximum transconductance (g_{m,max}) (represented by open circles) from 298K to 423K.

FIG. 5A shows off-state breakdown characteristics of AlN metal-semiconductor field-effect transistors with different gate-to-drain lengths. FIG. 5B shows breakdown voltages as a function of gate-to-drain length of the AlN metal-semiconductor field-effect transistors.

### DETAILED DESCRIPTION

This disclosure describes aluminum nitride (AlN) metal-semiconductor field-effect transistors grown and fabricated on single-crystal AlN substrates by metal-organic chemical vapor deposition. Devices with a drain-to-gate spacing of 15 μm have breakdown voltages that exceed 2 kV and exhibit drain saturation current and on/off ratio without regrown or graded contact layers.

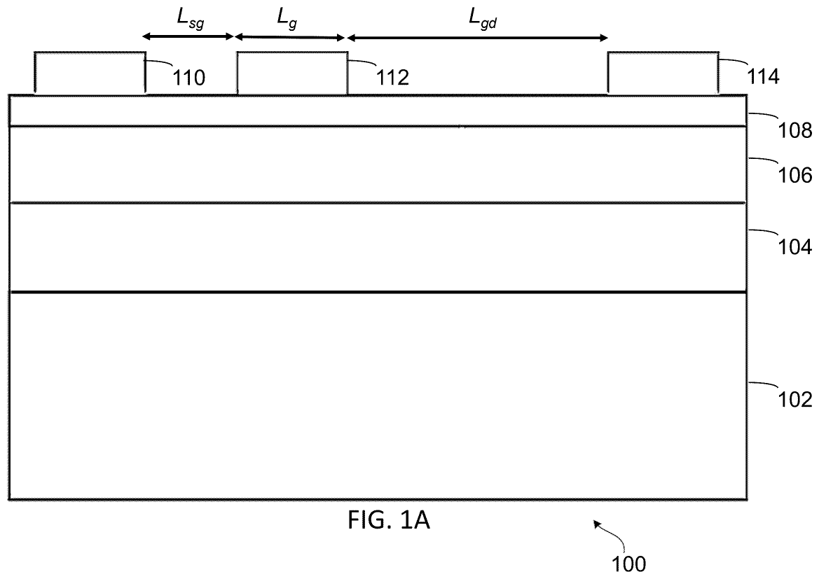

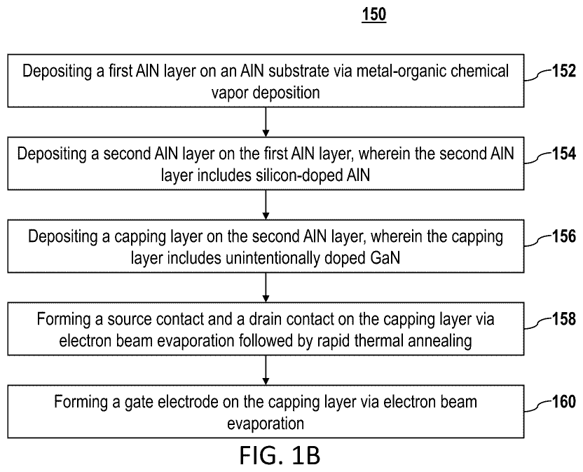

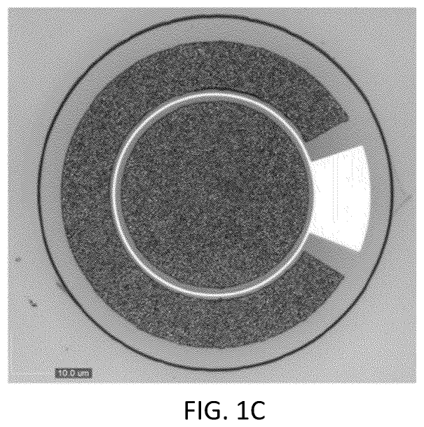

FIG. 1A is a cross-sectional schematic diagram of an example fabricated device 100. The device 100 includes an AlN substrate 102, an AlN buffer layer 104, a Si-doped n-AlN layer 106, a gallium nitride (GaN) capping layer 108, a source contact 110, a gate electrode 112, and a drain contact 114.

In some implementations, a thickness of the AlN substrate 102 is 550 μm. The AlN substrate 102 can be unintentionally doped. In some cases, a thickness of the AlN buffer layer 104 is 1 μm. The AlN buffer layer 104 can be unintentionally doped. The Si-doped n-AlN layer 106 serves as a channel. In some implementations, the Si-doped n-AlN layer 106 has a doping concentration of 1×10¹⁹ cm⁻³. In certain implementations, a thickness of the Si-doped n-AlN layer 106 is 200 nm. The unintentionally doped GaN layer capping layer 108 protects the AlN epilayers from surface oxidation when in contact with air after being removed from the growth chamber. An epilayer is a layer of material that is grown on a substrate through epitaxy. Epitaxy involves depositing a layer such that the crystal lattice of the deposited layer aligns with the lattice of the underlying substrate or layer. In some examples, a thickness of the unintentionally doped GaN capping layer 108 is 2 nm.

The source contact 110 can include a Ti/Al/Ti/Au (30 nm/100 nm/30 nm/50 nm) metal stack. In some examples, the source contact 110 can include a Ti/Al/Ni/Au metal stack. In some cases, the drain contact 114 includes a Ti/Al/Ti/Au (30 nm/100 nm/30 nm/50 nm) metal stack. In certain implementations, the drain contact includes a Ti/Al/Ni/Au metal stack. The gate electrode 112 can include a Ni/Au (30 nm/100 nm) metal stack.

Unintentional doping typically occurs when impurities are introduced accidentally or are inherent, due at least in part to contamination during fabrication, residual impurities from the raw materials, diffusion from surrounding layers or substrates, or defects in the crystal lattice that behave like dopants. Suitable examples of unintentional dopants include oxygen and carbon impurities.

The homoepitaxially grown AlN epilayer exhibits a smooth surface morphology with a root mean square roughness of approximately 0.4 nm, as measured by atomic force microscopy, and a low dislocation density on the order of 10⁴ cm⁻² by high-resolution X-ray diffraction. As used herein, “homoepitaxially grown” generally refers to a process where a crystalline layer is grown on a substrate of the same material and crystal structure. Compared with heteroepitaxial AlN on sapphire, homoepitaxial AlN on single-crystal AlN substrates had three orders of magnitude lower dislocation density, which can improve AlN device performance.

FIG. 1B is a flowchart showing example operations in process 150 for fabricating a metal-semiconductor field effect transistor.

In 152, a first AlN layer is deposited on an AlN substrate via metal-organic chemical vapor deposition. In some implementations, the metal-organic chemical vapor deposition occurs at a temperature in a range of about 1100° C. to about 1300° C. In some cases, the metal-organic chemical vapor deposition occurs at a pressure in a range of about 15 Torr to about 25 Torr. In 154, a second AlN layer is deposited on the first AlN layer. The second AlN layer includes silicon-doped AlN. In 156, a capping layer is deposited on the second AlN layer. The capping layer includes unintentionally doped GaN. In 158, a source contact and a drain contact are formed on the capping layer via electron beam evaporation, followed by rapid thermal annealing. In some cases, the rapid thermal annealing occurs in a nitrogen atmosphere. In 160, a gate electrode is formed on the capping layer via electron beam evaporation.

### EXAMPLES

The epilayers of aluminum nitride (AlN) metal-semiconductor field-effect transistors were grown via metal-organic chemical vapor phase deposition on single-crystal AlN substrates with a dislocation density of about 10³ cm⁻². The precursors for aluminum and nitrogen were trimethylaluminum (TMAl) and ammonia (NH₃), respectively. The n-type doping was achieved using silane (SiH₄) as the silicon source. The growth process was carried out at a temperature of 1250° C. and a pressure of 20 Torr.

The device fabrication started with surface cleaning, including hydrochloric acid dipping and ultrasonication in acetone, isopropyl alcohol, and deionized water to remove contamination on the sample surface. The AlN metal-semiconductor field-effect transistors were fabricated using photolithography and lift-off processes. Plasma reactive ion etching with BCl₃ was used for mesa isolation with a depth of approximately 700 nm into the AlN resistive buffer layer. The source and drain contacts, including a metal stack of Ti (30 nm)/Al (100 nm)/Ni (30 nm)/Au (50 nm), were formed by electron beam deposition, followed by rapid thermal annealing at 950° C. in a nitrogen atmosphere for 30 seconds. The gate electrode was a Ni (30 nm)/Au (100 nm) metal stack formed by electron beam deposition. A Keithly 4200 SCS semiconductor analyzer was used to carry out electrical measurements on a probe station with a thermal chuck. Reverse breakdown measurements were measured using a Keysight B1505A power device analyzer.

In an AlN metal-semiconductor field-effect transistor, both the source-to-gate length (L_{sg}) and gate length (L_{g}) were 2 μm, and the gate-to-drain length (L_{gd}) varied from 2 to 15 μm. FIG. 1C shows the top-view microscope image of the example AlN metal-semiconductor field-effect transistors with a gate-to-drain length of 4 μm.

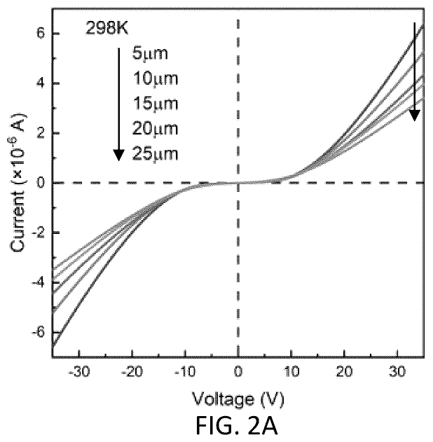

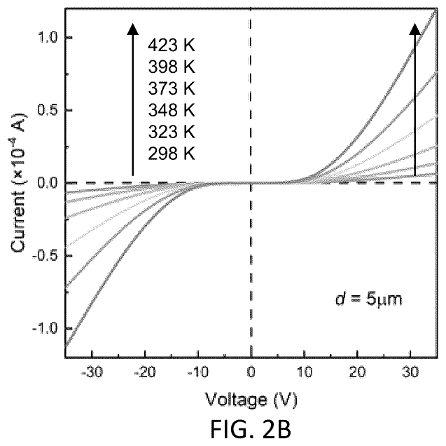

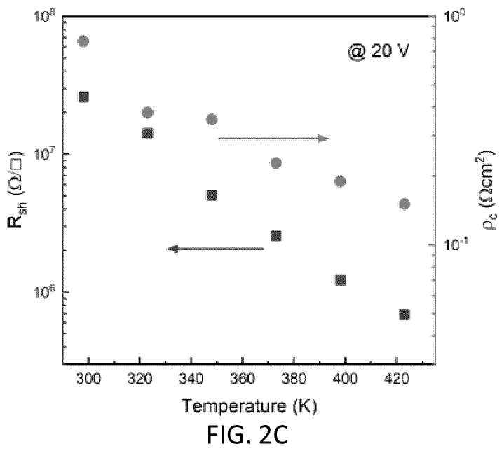

FIG. 2A illustrates the ohmic contact behavior of AlN at room temperature via the transmission line method. The arrow indicates the direction of increasing gap between the transmission line method pads (d) from 5 μm to 25 μm. As the gap between the transmission line method pads increased, the current decreased accordingly. The I-V characteristic of the AlN ohmic contact was non-linear, which can be typical for AlN and high Al-content AlGaN due at least in part to the high potential barrier at the metal/semiconductor interface.

FIG. 2B shows the I-V characteristic for d=5 μm of the temperature range from 298 K to 423 K. The arrow indicates the direction of increasing temperature. The film sheet resistance (Rₛ) (represented by squares) and the contact resistivity (ρ_{c}) (represented by circles) of ohmic contacts were extracted, as shown in FIG. 2C. Due at least in part to the non-linear nature of the I-V characteristics, the resistance was calculated at a specific voltage or current value. In this case, resistance was determined at 20 V by dividing the voltage by the corresponding current (R=V/I). A contact resistivity of 7.7×10⁻¹ Ωcm² was observed at room temperature and a minimum value of 1.5×10⁻¹ Ω·cm² at 473 K. This reduction in contact resistivity at high temperatures is likely due at least in part to easier passage of the thermally excited electrons through the metal/AlN interface by tunneling through an effective thinner potential barrier and/or thermionic emission. As shown in FIG. 2C, the sheet resistance (Rₛₕ), represented by squares, was 2.4×10⁷ Ω/sq. at room temperature and decreased to 6.6×10⁵ Ω/sq. at 423 K.

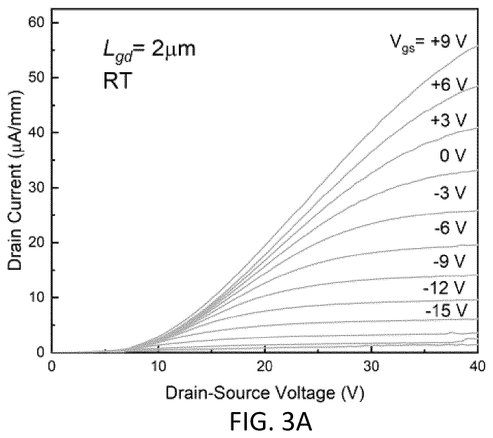

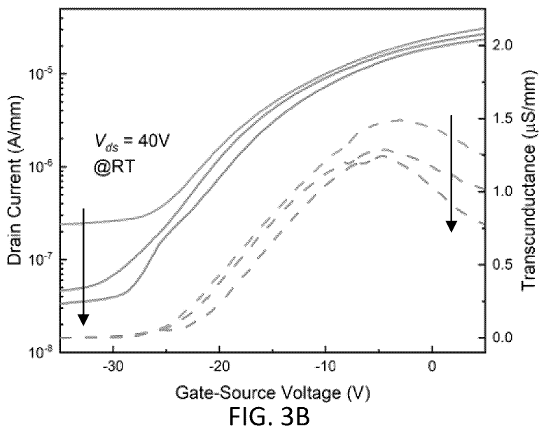

FIG. 3A shows the output characteristics of the AlN metal-semiconductor field-effect transistors with L_{gd}=2 μm at room temperature. The AlN metal-semiconductor field-effect transistors had a normally-on operation and pinch-off characteristics for gate voltage (V_{gd}) of <−20 V. Drain current (I_{ds}) was effectively modulated by gate bias (V_{gs}) and showed saturation. The maximum I_{ds} was 56 μA/mm for gate bias of +9 V. The drain current values can be attributed at least in part to the lower sheet resistance of the homoepitaxial AlN layer (2.4×10⁷ Ω/sq.) compared to the sheet resistance of AlN layer on sapphire (8×10⁷ Ω/sq.).

FIG. 3B shows the transfer characteristics for the AlN metal-semiconductor field-effect transistors with different gate-to-drain lengths from 2 μm to 8 μm at a drain bias (V_{ds}) of +40 V at room temperature. The smallest off-state drain current was 3.3×10⁻⁸ A/mm, and the on/off ratio was approximately 700 for devices with L_{gd}=8 μm. The maximum transconductance at room temperature was 1.49 μS/mm on devices with L_{gd}=2 μm.

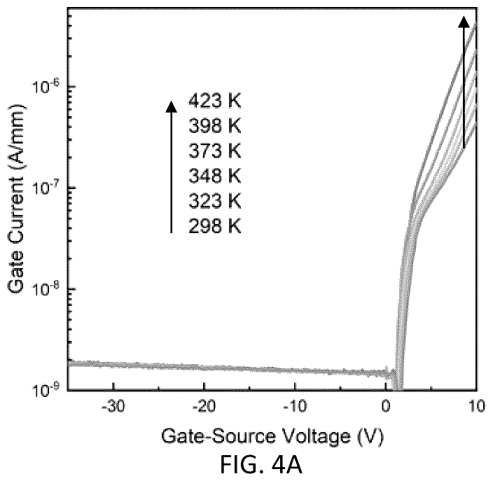

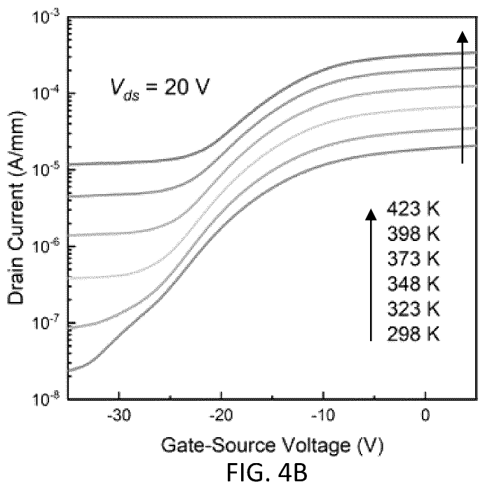

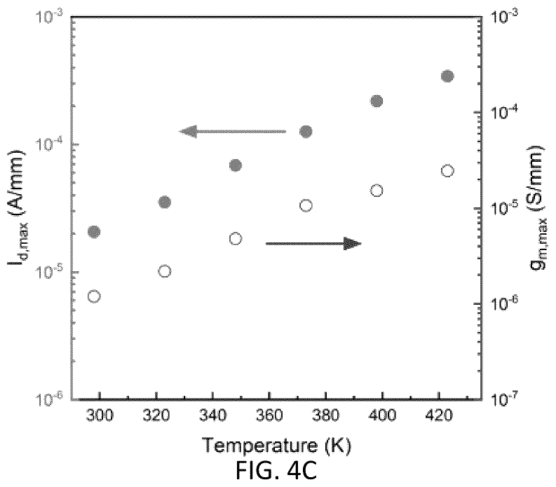

FIG. 4A shows gate current and gate-source voltage characteristics of the AlN metal-semiconductor field-effect transistors across a temperature range of 298K to 423K. The arrow indicates the direction of increasing temperature. The reverse gate leakage current (I_{g}) at a gate voltage of −20 V was less than 1.7×10⁻⁹ A/mm. Reverse gate leakage current was almost constant at all measured temperatures, showing the stable gate control with increasing temperature.

FIG. 4B shows the transfer characteristics of the AlN metal-semiconductor field-effect transistors with L_{gd}=4 μm at various temperatures ranging from 298K to 423K. FIG. 4C shows the maximum drain current (I_{d}) (represented by filled circles) and maximum transconductance (g_{m,max}) (represented by open circles) of the AlN metal-semiconductor field-effect transistors as a function of temperature. As temperature increased from room temperature to 423K, I_{d} increased from 2.06×10⁻⁵ to 3.42×10⁻⁴ A/mm, while maximum transconductance increased from 1.19×10⁻⁶ to 2.45×10⁻⁵ mS/mm. There was an increase in the electron concentration from 1×10¹⁵ to 5.6×10¹⁷ cm⁻³ as the temperature increased from room temperature to 500° C. with a relatively small reduction in mobility from 156 cm²/V·s to 52 cm²/V·s. The electrical conductance of the n-type AlN layer increased with rising temperature, leading to enhanced output performance at high temperatures. This is in contrast with wide-bandgap semiconductors like GaN and SiC, where the overall forward performance of field effect transistors based on these semiconductors deteriorates with increasing temperature, due at least in part to a dominant reduction in electron mobility by phonon scattering. In terms of device leakage, the off-state leakage current was about 2.4×10⁻⁸ A/mm at room temperature and increased with increasing temperature. The current leakage path was assessed by measuring the current flow through the unintentionally doped AlN buffer layer. The current flow through the unintentionally doped AlN buffer layer was found to be negligible compared to the off-state current. The gate leakage was also minimal at high temperatures. The increase in off-state leakage current at high temperatures can be a result of the enhanced electrical conductance in the AlN channel and the increased unmodulated channel electrons.

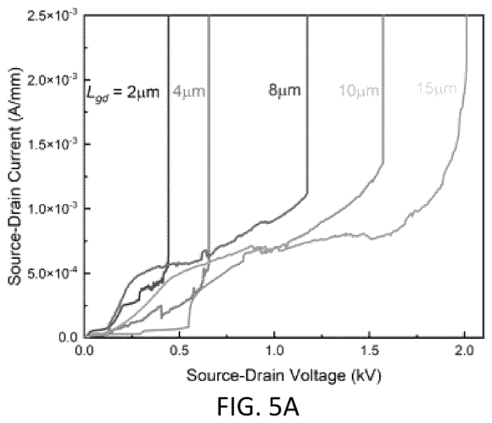

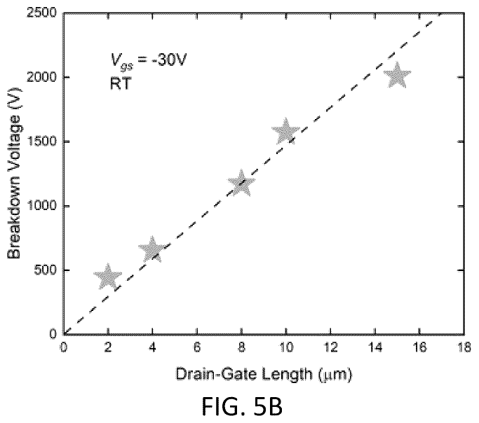

FIG. 5A shows the off-state breakdown characteristics of AlN metal-semiconductor field-effect transistors with the gate-to-drain length ranging from 2 μm to 15 μm. Destructive breakdown at the device edges was observed due at least in part to the electric field crowding effect.

FIG. 5B shows the breakdown voltage (V_{br}) of the AlN metal-semiconductor field-effect transistors as a function of gate-to-drain length. The gate bias was set to −30 V at room temperature. The device breakdown voltage increased from 442 V to 2010 V with increasing gate-to-drain length from 2 μm to 15 μm.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A metal-semiconductor field effect transistor comprising:
an AlN substrate;
an AlN buffer layer on the AlN substrate;
a Si-doped n-AlN layer on the AlN buffer layer;
a GaN capping layer on the Si-doped n-AlN layer;
a source contact on the GaN capping layer;
a drain contact on the GaN capping layer; and
a gate electrode on the GaN capping layer.

2. The metal-semiconductor field effect transistor of claim 1, wherein the AlN substrate comprises a single-crystal AlN substrate.

3. The metal-semiconductor field effect transistor of claim 2, wherein a dislocation density of the single-crystal AlN substrate is about 10³ cm⁻².

4. The metal-semiconductor field effect transistor of claim 1, wherein a thickness of the AlN buffer layer is about 1 μm.

5. The metal-semiconductor field effect transistor of claim 1, wherein a thickness of the Si-doped n-AlN layer is about 200 nm.

6. The metal-semiconductor field effect transistor of claim 1, wherein a Si doping concentration in the Si-doped n-AlN layer is about 1×10¹⁹ cm⁻³.

7. The metal-semiconductor field effect transistor of claim 1, wherein a thickness of the GaN capping layer is about 2 nm.

8. The metal-semiconductor field effect transistor of claim 1, wherein the GaN capping layer is unintentionally doped.

9. The metal-semiconductor field effect transistor of claim 1, wherein the source contact comprises Ti/Al/Ni/Au.

10. The metal-semiconductor field effect transistor of claim 1, wherein the drain contact comprises Ti/Al/Ni/Au.

11. The metal-semiconductor field effect transistor of claim 1, wherein the gate electrode comprises Ni/Au.

12. The metal-semiconductor field effect transistor of claim 1, wherein the AlN buffer layer is between the AlN substrate and the Si-doped n-AlN layer.

13. The metal-semiconductor field effect transistor of claim 1, wherein a breakdown voltage exceeds 2 kV for a drain-to-gate spacing of 15 μm.

14. The metal-semiconductor field effect transistor of claim 1, wherein a maximum drain current is about 56 μA/mm for a gate bias of +9 V.

15. The metal-semiconductor field effect transistor of claim 1, wherein an ON/OFF ratio is in a range of about 600 to about 800 for a drain-to-gate spacing of 8 μm.

16. The metal-semiconductor field effect transistor of claim 1, wherein the metal-semiconductor field effect transistor is thermally stable from 298 K to 423 K.

17. A method of fabricating a metal-semiconductor field effect transistor, the method comprising:
depositing a first AlN layer on an AlN substrate via metal-organic chemical vapor deposition;
depositing a second AlN layer on the first AlN layer, wherein the second AlN layer comprises silicon-doped AlN;
depositing a capping layer on the second AlN layer, wherein the capping layer comprises unintentionally doped GaN;
forming a source contact and a drain contact on the capping layer via electron beam evaporation followed by rapid thermal annealing; and
forming a gate electrode on the capping layer via electron beam evaporation.

18. The method of claim 17, wherein the metal-organic chemical vapor deposition occurs at a temperature in a range of about 1100° C. to about 1300° C.

19. The method of claim 17, wherein the metal-organic chemical vapor deposition occurs at a pressure in a range of about 15 Torr to about 25 Torr.

20. The method of claim 17, wherein the rapid thermal annealing occurs in a nitrogen atmosphere.
